(19) United States
(12) Patent Application Publication
(10) Pub. No.: US 2026/0082815 A1
(43) Pub. Date: Mar. 19, 2026

(54) OPPOSITE TOP AND BOTTOM ELECTRODES FOR MEMORY DEVICES

(71) Applicant: International Business Machines Corporation, Armonk, NY (US)

(72) Inventors: Oscar van der Straten, Guilderland Center, NY (US); Chih-Chao Yang, Glenmont, NY (US)

(21) Appl. No.: 18/890,322

(22) Filed: Sep. 19, 2024

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A memory device is provided that includes non-overlapping and vertically offset top and bottom electrodes. The top electrode and the bottom electrode are not aligned along a same vertical axis with respect to a plane of an underlying substrate. The top electrode is present above and along one side of a magnetic tunnel junction (MTJ)-containing pillar and the bottom electrode is present beneath and along an opposing side of the MTJ-containing pillar. The memory device is devoid of re-sputtered bottom electrode metal particles and has a reduced circular edge roughness.

### BACKGROUND

The present application relates to non-volatile random access memory technology, and more particularly to a memory device that includes a top electrode and a bottom electrode that are non-overlapping and vertically offset from each other.

Magnetoresistive random access memory (MRAM) is a non-volatile random access memory technology in which data is stored by magnetic storage elements. These elements are typically formed from two ferromagnetic plates, each of which can hold a magnetization, separated by a thin dielectric layer (i.e., a tunnel barrier). One of the two plates is a permanent magnetic set to a particular polarity (i.e., a magnetic reference layer); the other plate's magnetization can be changed to match that of an external field to store memory (i.e., a magnetic free layer). Such a configuration is known as a magnetic tunnel junction (MTJ)-containing pillar. In leading-edge or neuromorphic computing systems, an MTJ-containing pillar is typically embedded within a back-end-of-the-line (BEOL) structure.

### SUMMARY

A memory device is provided that includes non-overlapping and vertically offset top and bottom electrodes. The top electrode and the bottom electrode are not aligned along a same vertical axis with respect to a plane of an underlying substrate. The top electrode is present above and along one side of a MTJ-containing pillar and the bottom electrode is present beneath and along an opposing side of the MTJ-containing pillar. The memory device is devoid of re-sputtered bottom electrode metal particles and has a reduced circular edge roughness.

In one embodiment of the present application, the memory device includes a MTJ-containing pillar, a bottom electrode located beneath the MTJ-containing pillar, and a top electrode located above the MTJ-containing pillar. In such an embodiment, the bottom electrode and the top electrode are non-overlapping and vertically offset from each other.

In another embodiment, the memory device includes a MTJ-containing pillar, a bottom electrode located beneath the MTJ-containing pillar, and a top electrode located above the MTJ-containing pillar, in which the bottom electrode and the top electrode are located on opposite sides of a vertical axis that passes through a middle portion of the MTJ-containing pillar.

### BRIEF DESCRIPTION OF THE DRAWINGS

FIG. 1 is a cross sectional view of an exemplary memory device in accordance with an embodiment of the present application.

FIG. 2 is a cross sectional view of another exemplary memory device in accordance with an embodiment of the present application.

FIG. 3A is a cross sectional view of an exemplary structure that can be employed in the present application, the exemplary structure including a first electrically conductive structure embedded in a first interlayer dielectric (ILD) layer, and a dielectric cap located on the first ILD layer and the first electrically conductive structure.

FIG. 3B is a cross sectional view of the exemplary structure of FIG. 3A after forming a metal cap in the dielectric cap and on the first electrically conductive structure.

FIG. 3C is a cross sectional view of the exemplary structure of FIG. 3B after forming a patterned second ILD layer on the dielectric cap and the metal cap, the patterned second ILD layer having an opening that physically exposes a surface of the metal cap.

FIG. 3D is a cross sectional view of the exemplary structure of FIG. 3C after forming a sacrificial dielectric layer in the opening and on the physically exposed surface of the metal cap.

FIG. 3E is a cross sectional view of the exemplary structure of FIG. 3D after forming a MTJ-containing material stack on the patterned second ILD layer and the sacrificial dielectric layer.

FIG. 3F is a cross sectional view of the exemplary structure of FIG. 3E after forming a patterned dielectric hard mask on the MTJ-containing material stack.

FIG. 3G is a cross sectional view of the exemplary structure of FIG. 3F after patterning the MTJ-containing material stack into a MTJ-containing pillar utilizing the patterned dielectric hard mask as an etch mask, and removing the patterned dielectric hard mask.

FIG. 3H is a cross sectional view of the exemplary structure of FIG. 3G after forming an encapsulation spacer on the sidewall of the MTJ-containing pillar.

FIG. 3I is a cross sectional view of the exemplary structure of FIG. 3H after forming a third ILD layer laterally adjacent to, and above, the MTJ-containing pillar.

FIG. 3J is a cross sectional view of the exemplary structure of FIG. 3I after forming a bottom electrode forming patterned mask on the third ILD layer, the bottom electrode forming patterned mask having an opening formed therein that physically exposes a surface of the third ILD layer.

FIG. 3K is a cross sectional view of the exemplary structure of FIG. 3J after extending the depth of the opening through the third ILD layer to provide an extended depth opening that physically exposes a surface of the sacrificial dielectric layer.

FIG. 3L is a cross sectional view of the exemplary structure of FIG. 3K after removing the sacrificial dielectric layer to provide a bottom electrode opening in the both the third ILD layer and the second ILD layer and thereafter removing the bottom electrode forming patterned mask, the bottom electrode opening extending beneath a portion of the MTJ-containing pillar.

FIG. 3M is a cross sectional view of the exemplary structure of FIG. 3L after forming a bottom electrode in a lower portion of the bottom electrode opening, the bottom electrode extending beneath MTJ-containing pillar and located laterally adjacent to a first side of the MTJ-containing pillar.

FIG. 3N is a cross sectional view of the exemplary structure of FIG. 3M after forming ILD material in an upper portion of the bottom electrode opening.

FIG. 3O is a cross sectional view of the exemplary structure of FIG. 3N after forming a top electrode forming patterned mask on the third ILD layer, the top electrode forming patterned mask having an opening formed therein that physically exposes a surface of the third ILD layer.

FIG. 3P is a cross sectional view of the exemplary structure of FIG. 3O after forming a top electrode opening in the third ILD layer and thereafter removing the top electrode forming patterned mask, the top electrode opening extending on top of a portion of the MTJ-containing pillar and located laterally adjacent to a second side of the MTJ-containing pillar in which the second side of the MTJ-containing pillar is opposite the first side of the MTJ-containing pillar.

FIG. 3Q is a cross sectional view of the exemplary structure of FIG. 3P after forming a top electrode in the top electrode opening and laterally adjacent to the second side of the MTJ-containing pillar.

FIG. 3R is a cross sectional view of the exemplary structure of FIG. 3Q after forming a fourth ILD layer on the third ILD layer and the top electrode.

FIG. 3S is a cross sectional view of the exemplary structure of FIG. 3R after patterning the fourth ILD layer to have an opening formed in the fourth ILD layer that physically exposes at least the top electrode.

FIG. 4A is a cross sectional view of the exemplary structure of FIG. 3L after forming a bottom electrode diffusion barrier liner and a bottom electrode in a lower portion of the bottom electrode opening, the bottom electrode diffusion barrier liner and the bottom electrode extending beneath MTJ-containing pillar and located laterally adjacent to a first side of the MTJ-containing pillar.

FIG. 4B is a cross sectional view of the exemplary structure of FIG. 4A after forming a top electrode diffusion barrier liner and a top electrode in the third ILD layer and laterally adjacent to a second side of the MTJ-containing pillar, the second side of the MTJ-containing pillar is opposite the first side of the MTJ-containing pillar.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10°deviation in angle.

For high performance MRAM devices based on perpendicular MTJ-containing pillars, well-defined interfaces and interface control are essential. Embedded MTJ-containing pillars are usually formed by patterning a blanket MTJ-containing material stack utilizing one of reactive ion etching (RIE) and ion beam etching (IBE). Processing the blanket MTJ-containing material stack into a MTJ-containing pillar utilizing RIE and IBE presents a major challenge as it leads to shorts caused by re-sputtered bottom electrode metal particles on the sidewall of the MTJ-containing pillar. A memory device which is devoid of re-sputtered bottom electrode metal particles on the sidewall of the MTJ-containing pillar is desired.

Another problem that arises with processing the blanket MTJ-containing material stack is that a polycrystalline metal hard mask is used during the patterning of the blanket MTJ-containing material stack. Grain boundaries and/or defects in the polycrystalline metal hard mask can be transferred into the MTJ-containing pillar during patterning of the blanket MTJ-containing material stack resulting in MTJ-containing pillars with high circular edge roughness (CER) which can negatively impact memory device performance.

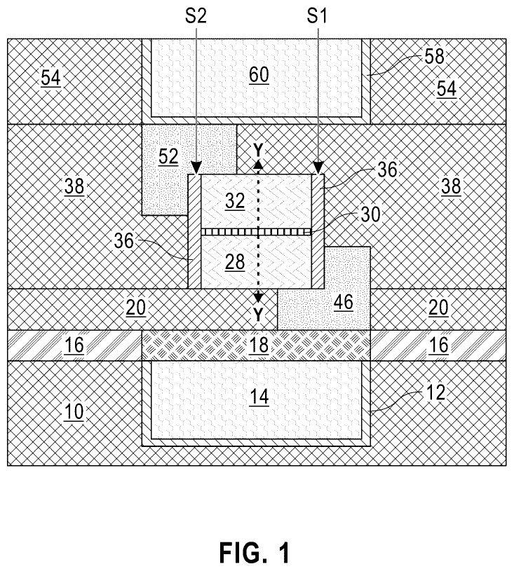

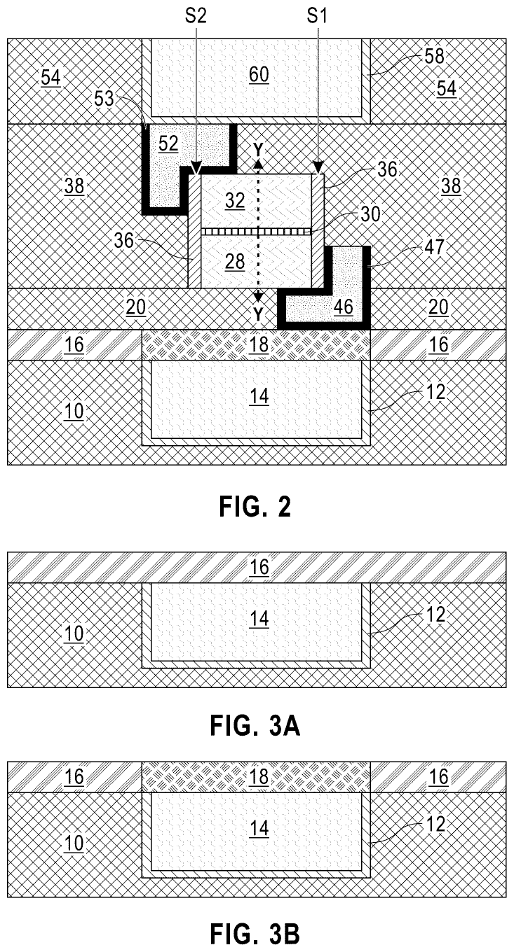

The present application provides a memory device as illustrated in FIG. 1 or FIG. 2 that includes top electrode 52 and bottom electrode 46 that are non-overlapping and vertically offset from each other. The term “non-overlapping” is used in the present application to denote that no portion of the top electrode is in a same area as the bottom electrode. The term “vertically offset” denotes that the top electrode and bottom electrode are not located on a same horizontal plane. Notably, the top electrode 52 and the bottom electrode 46 are not aligned along a same vertical axis (i.e., a vertical Y-Y axis as shown in FIGS. 1 and 2; in the present application Y-Y passes through a middle portion of the MTJ-containing pillar) with respect to a plane of a substrate (i.e., the first ILD layer 10). As is illustrated in FIGS. 1 and 2, the top electrode 52 is located entirely on one side of the vertical Y-Y axis, and the bottom electrode 46 is located entirely on another side of the vertical Y-Y axis. In the memory devices illustrated in FIGS. 1 and 2, the top electrode 52 is present above and along one side (i.e., the second side, S2) of a MTJ-containing pillar (the MTJ containing pillar includes bottom magnetic material containing layer 28, tunnel barrier layer 30 and upper magnetic material containing layer 32) and the bottom electrode 46 is present beneath and along an opposing side (i.e., the first side, S1) of the MTJ-containing pillar.

As is illustrated in both FIGS. 1 and 2, each of the illustrated memory devices further includes first electrically conductive structure 14 embedded in first ILD layer 10. An optional first diffusion barrier liner 12 can be present along a sidewall and bottommost surface of the first electrically conductive structure 14. The memory devices illustrated in FIGS. 1 and 2 also include metal cap 18 that is located on a surface of at least the first electrically conductive structure 14 (the metal cap 18 can extend onto a surface of the optional first diffusion barrier layer 12, if the same is present). The metal cap 18 is embedded in a dielectric cap 16 that is present on the first ILD layer 10, the first electrically conductive structure 14 and, if present, the first diffusion barrier layer 12. Bottom electrode 46 is electrically connected to the first electrically conductive structure 14 (through the metal cap 18) and to the MTJ-containing pillar. The electrically connection of the bottom electrode 46 to the MTJ-containing pillar can be a direct electrical connection as illustrated in FIG. 1, or an indirect electrical connection due to the bottom electrode diffusion barrier liner 47 that is present in the memory device illustrated in FIG. 2. As is illustrated in FIGS. 1 and 2, bottom electrode 46 extends beneath the MTJ-containing pillar and is present laterally adjacent to a first side, S1, of the MTJ-containing pillar. Encapsulation spacer 36 is present on a sidewall of the MTJ-containing pillar. The encapsulation spacer 36 can protect and provide passivation to the MTJ-containing pillar. Top electrode 52 is electrically connected to the MTJ-containing pillar and to a second electrically conductive structure 60. An optional second diffusion barrier liner 58 can be present on a sidewall and a bottom surface of the second electrically conductive structure 60. The electrical connection of the top electrode 52 to the MTJ-containing pillar can be a direct electrical connection as illustrated in FIG. 1, or an indirect electrical connection due to the top electrode diffusion barrier liner 53 that is present in the memory device illustrated in FIG. 2.

Although FIG. 2 shows the presence of bottom electrode diffusion barrier liner 47 and top electrode diffusion barrier liner 53, embodiments are contemplated in which only one of the electrode diffusion barrier liners (i.e., bottom electrode diffusion barrier liner 47 or top electrode diffusion barrier liner 53) is present. Typically, the top electrode 52 includes top electrode diffusion barrier liner 53, while the bottom electrode 46 is devoid of bottom electrode diffusion barrier liner 47.

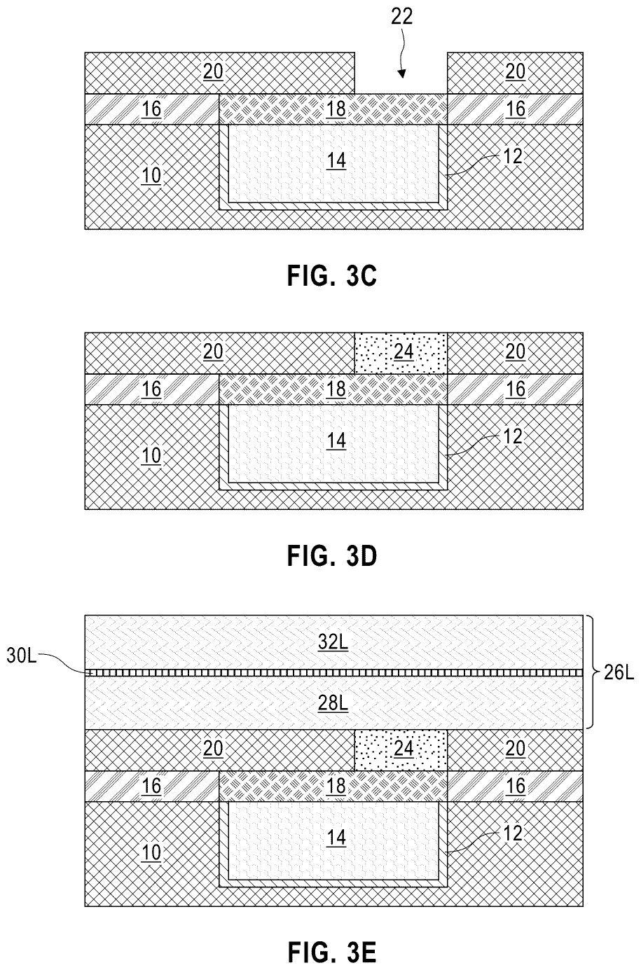

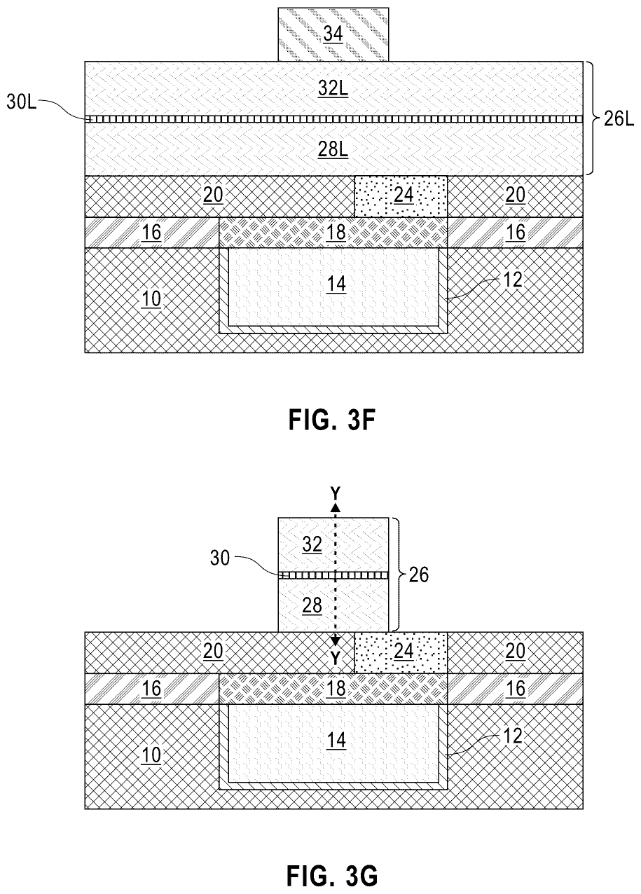

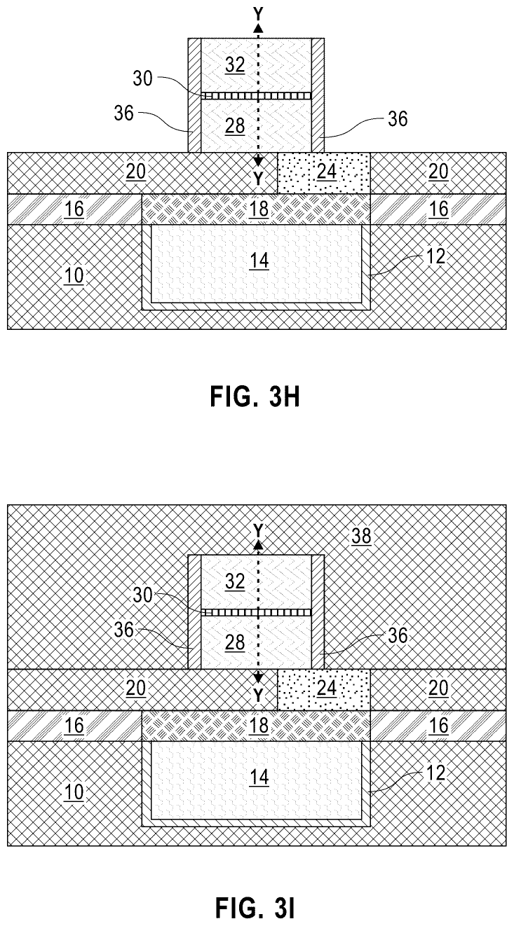

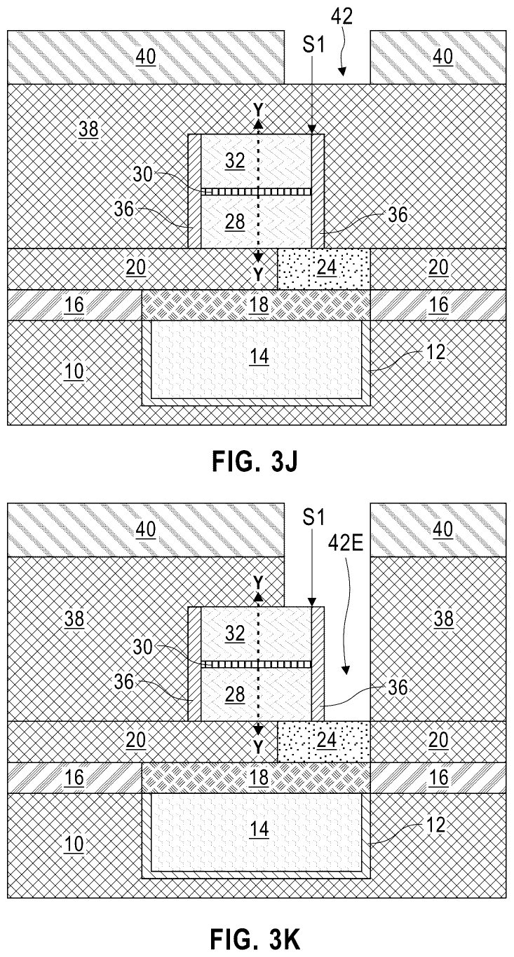

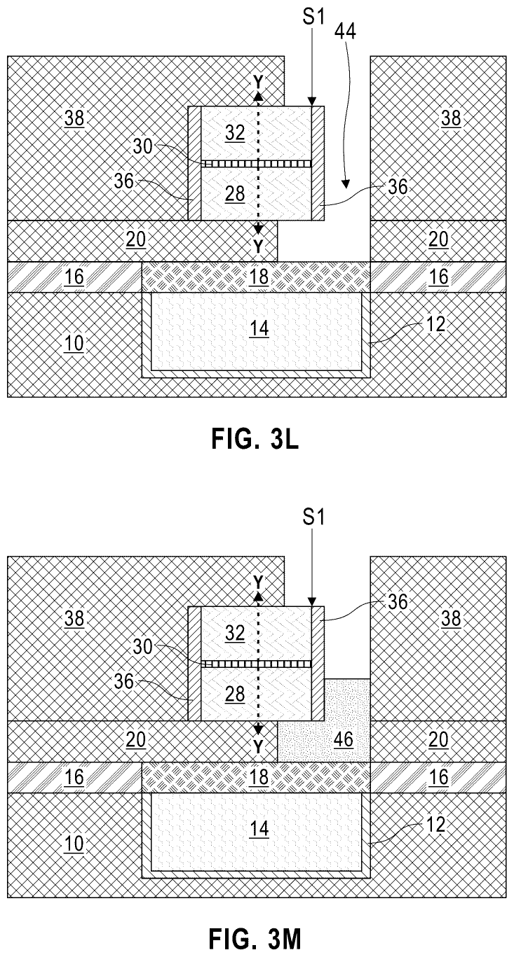

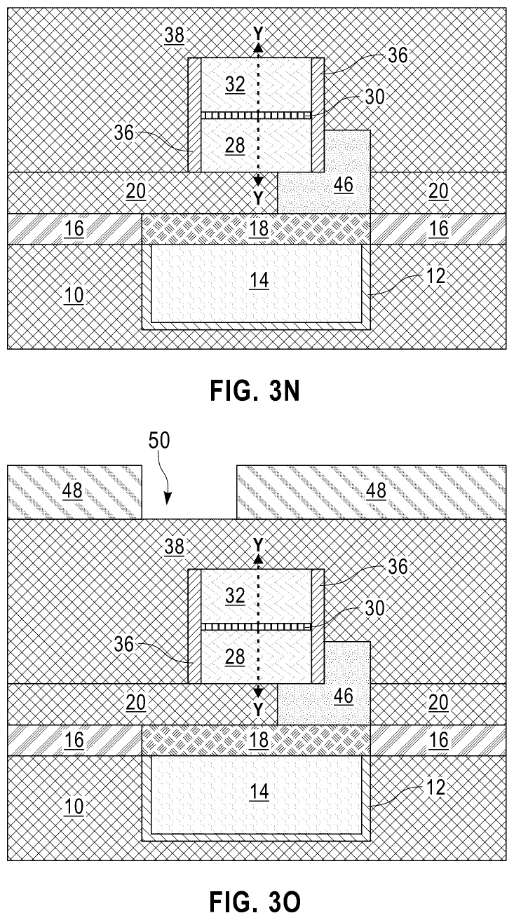

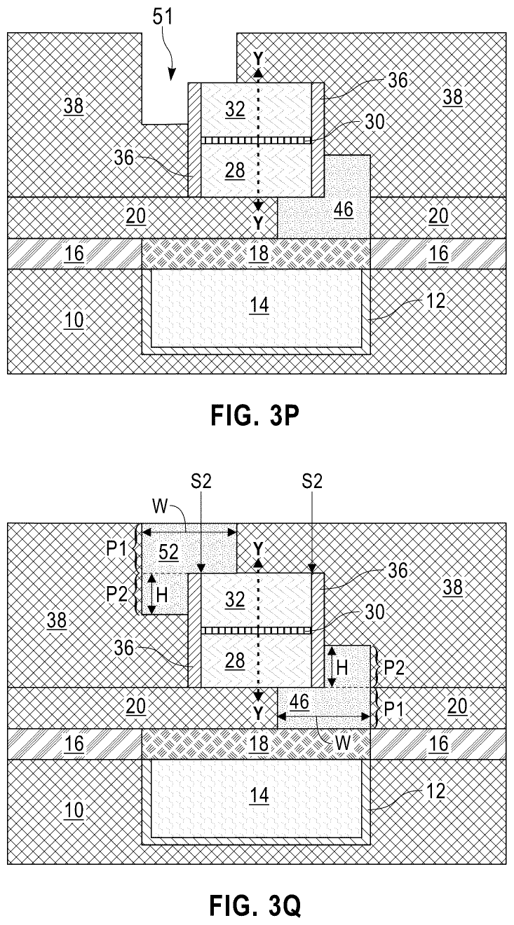

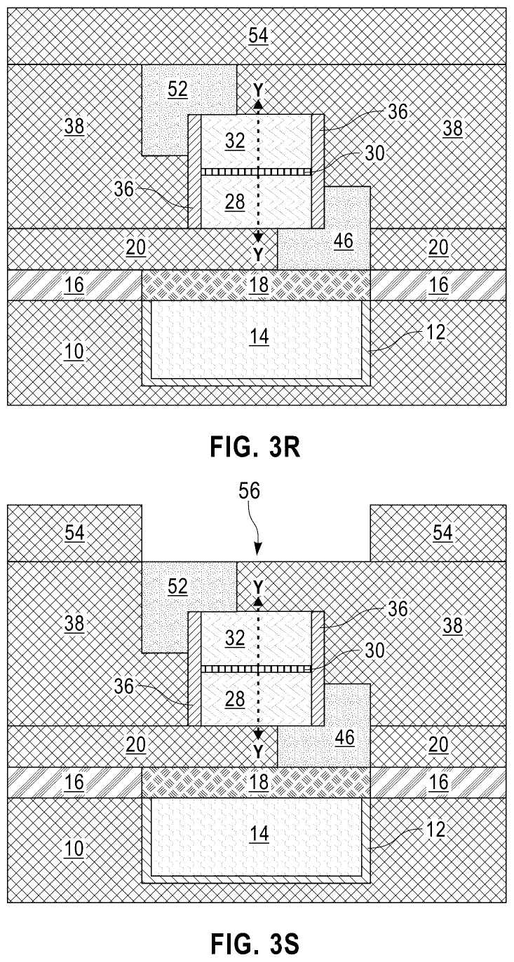

The top electrode 52 and the bottom electrode 46 have a horizontal portion, P1, that is connected to a vertical portion, P2; See, for example, FIG. 3Q. In the present application, the lateral width, W, of the horizontal portion, P1, of the top electrode 52 and the bottom electrode 46 is greater than a vertical height, H, of the vertical portion, P2, of the top electrode 52 and the bottom electrode 46.

Various other ILD layers besides the first ILD layer 10 (i.e., patterned second ILD layer 20, third ILD layer 38, and fourth ILD layer 54) can also be present. As is illustrated, a bottom portion of the bottom electrode 46 can be embedded in the patterned second ILD layer 20, while a top portion of the bottom electrode 46 can be embedded in the third ILD layer 38. The third ILD layer 38 also embeds the MTJ-containing pillar, the encapsulation spacer 36, and the top electrode 52. The fourth ILD layer 54 embeds the second electrically conductive structure 60. Although the memory devices are described and illustrated as having a single MTJ-containing pillar, the memory devices of the present application can have a plurality of MTJ-containing pillars in which all of the MTJ-containing pillars or some set of MTJ-containing pillars of the plurality of MTJ-containing pillars contains top electrodes and bottom electrodes that are non-overlapping and vertically offset from each other.

The memory devices illustrated in FIGS. 1 and 2 extend the scalability of MRAM/memory elements due to an enlarged process window for MTJ-containing material stack patterning. The memory devices illustrated in FIGS. 1 and 2 also have enhanced performance of embedded MRAM due to reduced risks of shorts caused by re-sputtered bottom electrode metal particles being present on a sidewall of the MTJ-containing pillar. Also, the memory devices illustrated in FIGS. 1 and 2 contain MTJ-containing pillars in which the circular edge roughness has been reduced by utilizing a dielectric hard mask to pattern the MTJ-containing material stack.

Reference is now made to FIGS. 3A-3S which illustrate a process flow that can be employed in the present application in forming the memory device illustrated in FIG. 1. This process flow begins by providing the exemplary structure illustrated in FIG. 3A. Notably, the exemplary structure illustrated in FIG. 3A includes first electrically conductive structure 14 embedded in first ILD layer 10, and dielectric cap 16 is located on the first ILD layer 10 and the first electrically conductive structure 14. In some embodiments and as is illustrated in FIG. 3A, a first diffusion barrier liner 12 can be present along a sidewall and a bottommost surface of the first electrically conductive structure 14. In other embodiments, the first diffusion barrier liner 12 can be omitted. Collectively, the first electrically conductive structure 14, the optional first diffusion barrier liner 12 and the first ILD layer 10 provide a metal (or interconnect) level, Mₙ, of a BEOL structure, wherein n is any integer starting from 1; the upper limit of ‘n’ can vary and can be predetermined by the manufacturer of a specific integrated circuit. Although FIG. 3A describes and illustrates a single first electrically conductive structure 14 embedded in the first ILD layer 10, the present application contemplates embodiments when more than one first electrically conductive structure 14 is embedded in the first ILD layer 10. When more than one first electrically conductive structure 14 is embedded in the first ILD layer 10, some or all of the first electrically conductive structures can be processed to include the non-overlapping and vertically offset top and bottom electrodes in accordance with the present application.

In some embodiments, the first electrically conductive structure 14 can extend entirely through the first ILD layer 10. In other embodiments, the first electrically conductive structure 14 extends partially through the first ILD layer 10 and in such embodiments, the first electrically conductive structure 14 can be connected to another electrically conductive structure such as, for example, a metal line and/or a metal via.

Although not illustrated in any of the drawings of the present application, a substrate can be located beneath metal level, Mₙ. The substrate can include a front-end-of-the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level that includes a plurality of lower interconnect structures embedded in a lower interconnect dielectric material layer; or any combination thereof. In one example, the substrate includes a FEOL level and a MOL level.

The metal level, Mₙ, can be formed utilizing techniques that are known to those skilled in the art. In one embodiment, a damascene process can be used in forming metal level, Mₙ. A damascene process can include forming at least one opening into the first ILD layer 10, filling the opening with an optional diffusion barrier layer, and an electrically conductive material and, if needed, performing a planarization process such as, for example, chemical mechanical polishing (CMP) to remove the optional diffusion barrier layer and the electrically conductive material from the topmost surface of the first ILD layer 10. The diffusion barrier layer that remains in the opening can be referred to herein as the first diffusion barrier liner 12, and the electrically conductive material that remains in the opening can be referred to herein as the first electrically conductive structure 14. In some embodiments, and as shown in FIG. 3A, the first electrically conductive structure 14 has a topmost surface that is substantially coplanar with a topmost surface of the first ILD layer 10 as well as with a topmost surface of the first diffusion barrier liner 12, if the same is present.

The first ILD layer 10 can be composed of a dielectric material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein are measured in a vacuum unless otherwise noted. Illustrative low-k dielectric materials that can be used as the first ILD layer 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Although not shown, the first ILD layer 10 can include a multilayered structure that includes at least two different dielectric materials stacked one atop the other. The first ILD layer 10 can be formed utilizing a deposition process including, for example, chemical vapor deposition (CVD), plasma enhanced chemical vapor deposition (PECVD), evaporation or spin-on coating.

The diffusion barrier layer (and thus the first diffusion barrier liner 12) that can optionally be employed in the present application includes a diffusion barrier material (i.e., a material that serves as a barrier to prevent a conductive material such as copper from diffusing there through). Examples of diffusion barrier materials that can be used in providing the diffusion barrier layer (and thus the first diffusion barrier liner 12) include, but are not limited to, Ta, TaN, Ti, TiN, Ru, RuN, RuTa, RuTaN, W, or WN; in some instances of the present application chemical symbols, as found in the Periodic Table of Elements, are used instead of the full names of the elements or compounds. In some embodiments, the diffusion barrier material can include a material stack of diffusion barrier materials. In one example, the diffusion barrier material can be composed of a stack of Ta/TaN. The diffusion barrier layer can be formed by a deposition process such as, for example, CVD, PECVD, or physical vapor deposition (PVD).

The electrically conductive material that provides the first electrically conductive structure 14 can include an electrically conductive metal and/or an electrically conductive metal alloy. Illustrative examples of electrically conductive metals include, but are not limited to, Cu, W, Al, Co, or Ru. An illustrative example of an electrically conductive metal alloy includes Cu—Al alloy. The electrically conductive material that provides first electrically conductive structure 14 can be formed by a deposition process such as, for example, CVD, PECVD, PVD, sputtering or electroplating. In some embodiments, a reflow anneal can follow the deposition of the electrically conductive material that provides first electrically conductive structure 14. The electrically conductive structure 14 can be a metal via, a metal liner or a combined metal line/metal via.

After forming the metal level, Mₙ, dielectric cap 16 is formed. Dielectric cap 16 is composed of a dielectric capping material which is compositionally different from the dielectric material that provides the first ILD layer 10. The dielectric capping material that provides the dielectric cap 16 can include, but is not limited to, silicon nitride (SiN), or a dielectric containing atoms of silicon, nitrogen and carbon (i.e., SiNC). The dielectric cap 16 can be formed by a deposition process including, but not limited to, atomic layer deposition (ALD), CVD, PECVD or PVD.

Referring now to FIG. 3B, there is illustrated the exemplary structure of FIG. 3A after forming a metal cap 18 in the dielectric cap 16 and on the first electrically conductive structure 12. Metal cap 18 formation includes patterning the dielectric cap 16 to physically expose the first electrically conductive structure 14. The patterning of the dielectric cap 16 includes lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In the present application, the patterning of the dielectric cap 16 forms an opening in the dielectric cap 16 that physically exposes (all or a portion of) the first electrically conductive structure 14. In some embodiments, the opening can also physically expose a topmost surface of the first diffusion barrier liner 12, if the first diffusion barrier liner 12 is present. In other embodiments, the opening formed in the dielectric cap does not physically expose the first diffusion barrier liner 12.

The metal cap 18 formation continues by selecting a metal that is inert as compared to the electrically conductive material present in the first electrically conductive structure 14, and then forming the metal cap 18 in the opening present in the dielectric cap 16 by a deposition process, followed by planarization process including chemical mechanical planarization (CMP). The deposition process used in forming the metal cap 18 can include, for example, CVD, PECVD, PVD, sputtering or electroplating. Illustrative examples of such inert metals that can be used in providing the metal cap 18 include, but are not limited to, Ta, W or Ru. As illustrated in FIG. 3B, the metal cap 18 has a topmost surface that is substantially coplanar with a topmost surface of the dielectric cap 16.

Referring now to FIG. 3C, there is illustrated the exemplary structure of FIG. 3B after forming a patterned second ILD layer 20 on the dielectric cap 16 and the metal cap 18, the patterned second ILD layer 20 having an opening 22 that physically exposes a surface of the metal cap 18. The forming of the patterned second ILD layer 20 begins by depositing a second ILD layer on the on the dielectric cap 16 and the metal cap 18. The depositing of the second ILD layer can include, for example, CVD, PECVD, evaporation or spin-on coating. A planarization process such as, for example, CMP, can follow the deposition of the second ILD layer. The second dielectric layer includes a dielectric material as mentioned above for the first ILD layer 10. The dielectric material that provides the second ILD layer can be compositionally the same as, or compositionally different from, the dielectric material that provides the first ILD layer 10.

The forming of the patterned second ILD layer 20 continues by patterning the second ILD layer by lithographic patterning as described above to provide the patterned second ILD layer 20 having opening 22 formed therein. As illustrated in FIG. 3C, opening 22 physically exposes a portion of the underlying metal cap 18; a remaining portion of the metal cap 18 is covered by the second patterned ILD layer 20.

Referring now to FIG. 3D, there is illustrated the exemplary structure of FIG. 3C after forming a sacrificial dielectric layer 24 in opening 22 and on the physically exposed surface of the metal cap 18. The sacrificial dielectric layer 24 is formed in opening 22 by depositing a sacrificial dielectric material in the opening 22 and on top of the patterned second ILD layer 20, and then a planarization process such as, for example, CMP, can follow the deposition of the sacrificial dielectric material to remove any sacrificial dielectric material that is formed on top of the patterned second ILD layer 20, the remaining sacrificial dielectric material present in the opening 22 forms the sacrificial dielectric layer 24 illustrated in FIG. 3D. The sacrificial dielectric material is composed of a dielectric material that is compositionally different from the dielectric material that provides the patterned second dielectric layer 20. Illustrative examples of sacrificial dielectric materials that can be used in providing the sacrificial dielectric layer 24 include, but are not limited to, HfON or AlON. As illustrated in FIG. 3D, the sacrificial dielectric layer 24 has a topmost surface that is substantially coplanar with a topmost surface of the patterned second ILD layer 20.

Referring now to FIG. 3E, there is illustrated the exemplary structure of FIG. 3D after forming a MTJ-containing material stack 26L on the patterned second ILD layer 20 and the sacrificial dielectric layer 24. The MTJ-containing material stack 26L includes a blanket bottom magnetic material containing layer 28L, a blanket tunnel barrier layer 30L and a blanket upper magnetic material containing layer 32L. The blanket bottom magnetic material containing layer 28L includes a magnetic pinned (or reference) material or a magnetic free material. The blanket upper magnetic material containing layer 32L includes the other of the magnetic pinned material or magnetic free material not employed as the blanket bottom magnetic material containing layer 28L. In one example, the blanket bottom magnetic material containing layer 28L includes a magnetic pinned (or reference) material, and the blanket upper magnetic material containing layer 32L includes a magnetic free material. In another example, the blanket bottom magnetic material containing layer 28L includes a magnetic free material, and the blanket upper magnetic material containing layer 32L includes a magnetic pinned (or reference) material.

In embodiments in which MTJ-containing material stack 26L includes a magnetic pinned (or reference) material as the blanket bottom magnetic material containing layer 28L and a magnetic free material as the blanket upper magnetic material containing layer 32L, the MTJ-containing material stack 26L (and the subsequently formed MTJ-containing pillar 26) can be referred to as a bottom pinned MTJ-containing material stack (or bottom pinned MTJ-containing pillar). In embodiments in which MTJ-containing material stack 26L includes a magnetic free material as the blanket bottom magnetic material containing layer 28L and a magnetic pinned (or reference) material as the blanket upper magnetic material containing layer 32L, the MTJ-containing material stack 26L (and the subsequently formed MTJ-containing pillar 26) can be referred to as a top pinned MTJ-containing material stack (or top pinned MTJ containing pillar).

In some embodiments, the bottom pinned MTJ-containing material stack can also include an optional blanket layer of metal seed material (not shown). In the bottom pinned MTJ-containing material stack, the optional blanket layer of metal seed material is formed directly beneath the blanket bottom magnetic material containing layer 28L. In some embodiments, the top pinned MTJ-containing material stack can also include an optional blanket layer of metal seed material (not shown). In the top pinned MTJ-containing material stack, the optional blanket layer of metal seed material is formed directly beneath the blanket upper magnetic material containing layer 32L.

In some embodiments, the MTJ-containing material stack 26L can also include a blanket layer of MTJ cap material (not shown) located on the blanket upper magnetic material containing layer 32L. In some embodiments, the magnetic free material can be composed of a single magnetic free material or a multilayered stack of magnetic free materials. In some embodiments, the magnetic free material includes a non-magnetic spacer material located between a first magnetic free material and a second magnetic free material.

The magnetic pinned material has a fixed magnetization. The magnetic pinned material can be composed of a metal or metal alloy (or a stack thereof) that includes one or more metals exhibiting high spin polarization. In alternative embodiments, exemplary metals for the formation of the magnetic pinned material include iron, nickel, cobalt, chromium, boron, or manganese. Exemplary metal alloys can include the metals exemplified by the above. In another embodiment, the magnetic pinned material can be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that can be used include a metal such as cobalt, nickel, platinum, palladium, iridium, or ruthenium, and can be arranged as alternating layers. The strong PMA region can also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys can be arranged as alternating layers. In one embodiment, combinations of these materials and regions can also be employed as the magnetic pinned material.

The blanket tunnel barrier layer 30L is composed of an insulator material and is formed at such a thickness as to provide an appropriate tunneling resistance. Exemplary materials for the blanket tunnel barrier layer 30L include magnesium oxide, aluminum oxide, and titanium oxide, or materials of higher electrical tunnel conductance, such as semiconductors or low-bandgap insulators.

The magnetic free material can be composed of a magnetic material (or a stack of magnetic materials) with a magnetization that can be changed in orientation relative to the magnetization orientation of the magnetic pinned layer. It is noted that the term “magnetic free material” denotes that the magnetic material does not have a fixed magnetization as is the case with magnetic pinned materials, but instead it is free to rotate upon application of an applied voltage. Exemplary magnetic materials for the magnetic free material include alloys and/or multilayers of cobalt, iron, alloys of cobalt-iron, nickel, alloys of nickel-iron, and alloys of cobalt-iron-boron.

If present, the non-magnetic metallic spacer material is composed of a non-magnetic metal or metal alloy that allows magnetic information to be transferred therethrough and also permits the two magnetic free layers to couple together magnetically, so that in equilibrium the first and second magnetic free layers are always parallel. The non-magnetic metallic spacer material allows for spin torque switching between a first magnetic free material and a second magnetic free material. The first magnetic free material and the second magnetic free material can include one of the magnetic free materials mentioned. The first magnetic free material can be compositionally the same as, or compositionally different from, the second magnetic free material.

The optional blanket layer of metal seed material can be composed of Pt, Pd, Ni, Rh, Ir, Re or alloys and multilayers thereof. In one example, the optional blanket layer of metal seed material is composed of Pt. If present, the blanket layer of MTJ cap material can be composed of Nb, NbN, W, WN, Ta, TaN, Ti, TiN, Ru, Mo, Cr, V, Pd, Pt, Rh, Sc, Al or other high melting point metals or conductive metal nitrides.

The MTJ-containing material stack 26L can be formed by utilizing one or more deposition processes such as, for example, sputtering, plasma enhanced atomic layer deposition (PEALD), PECVD or PVD.

Referring now to FIG. 3F, there is illustrated the exemplary structure of FIG. 3E after forming a patterned dielectric hard mask 34 on the MTJ-containing material stack 26L. The patterned dielectric hard mask 34 is composed of a dielectric hard mask material such as, for example, silicon dioxide, silicon nitride and/or silicon oxynitride. The patterned dielectric hard mask 34 can be formed by deposition of a blanket layer of dielectric hard mask material on the MTJ-containing material stack 26L, followed by lithographic patterning as defined above. The deposition of the blanket layer of dielectric hard mask material can include, but is not limited to, CVD, PECVD or PVD.

Referring now to FIG. 3G, there is illustrated the exemplary structure of FIG. 3F after patterning the MTJ-containing material stack 26L into a MTJ-containing pillar 26 utilizing the patterned dielectric hard mask 34 as an etch mask, and removing the patterned dielectric hard mask 34. In the present application, the MTJ-containing pillar 26 is designed to be formed on a portion of the patterned second ILD layer 20 and a portion of the sacrificial dielectric layer 24 as is illustrated in FIG. 3G. FIG. 3G further illustrates that another portion of the sacrificial dielectric layer 24 is physically exposed after forming the MTJ-containing pillar 26; the also for subsequent access to, and removal of, the sacrificial dielectric layer 24.

The patterning of the MTJ-containing material stack 26L includes an etching process such as, for example, IBE, RIE or plasma etching in which the patterned dielectric hard mask 34 is used as an etch mask. Since the MTJ-containing material stack 26L is formed on the patterned second ILD layer 20 and the sacrificial dielectric layer 24 instead of a bottom electrode as is the case in most prior art processes, there is no metal re-sputtering risk from the bottom electrode during the MTJ-containing material stack 26L patterning process. Thus, the sidewall of the MTJ-containing pillar 26 which is formed is devoid of re-sputtered bottom electrode metal particles. Also, there is a low circular edge roughness in the MTJ-containing pillar 26 due to utilizing the patterned dielectric hard mask 34 as compared to prior art MTJ-containing pillars in which a metal hard mask is used during the patterning of a MTJ-containing material stack.

The MTJ-containing pillar 26 includes a bottom magnetic material containing layer 28, a tunnel barrier layer 30 and an upper magnetic material containing layer 32. In the present application, the bottom magnetic material containing layer 28 is a non-etched portion of the blanket bottom magnetic material containing layer 28L that is located beneath the patterned dielectric hard mask 34, the tunnel barrier layer 30 is a non-etched portion of the blanket tunnel barrier layer 30L that is located beneath the patterned dielectric hard mask 34, and the upper magnetic material containing layer 32 is a non-etched portion of the blank upper magnetic material containing layer 32L that is located beneath the patterned dielectric hard mask 34. A vertical Y-Y axis is shown in a middle of the MTJ-containing pillar illustrated in FIG. 3G for the purpose of defining the subsequently regions in which the top and bottom electrodes will be subsequently formed.

After forming the MTJ-containing pillar 26, the patterned dielectric hard mask 34 is removed from the top of the MTJ-containing pillar 26. The removal of the patterned dielectric hard mask 34 includes a material removal process that is selective in removing the dielectric hard mask 34 from the exemplary structure. The removal of the patterned dielectric hard mask 34 reveals the MTJ-containing pillar 26 that was previously formed.

Referring now to FIG. 3H, there is illustrated the exemplary structure of FIG. 3G after forming an encapsulation spacer 36 on the sidewall of the MTJ-containing pillar 26. The encapsulation spacer 36 is also formed on a portion of the physically exposed sacrificial dielectric layer 24. The encapsulation spacer 36 is composed of an encapsulation dielectric material that can provide passivation to the MTJ-containing pillar 26. In some embodiments, the encapsulation dielectric material that provides the encapsulation spacer 36 can be composed of silicon nitride. In other embodiments, the encapsulation dielectric material that provides the encapsulation spacer 36 contains atoms of silicon, carbon and hydrogen. In some embodiments, and in addition to atoms of carbon and hydrogen, the encapsulation dielectric material that provides encapsulation spacer 36 can include atoms of at least one of nitrogen and oxygen. In other embodiments, and in addition to atoms of silicon, nitrogen, carbon and hydrogen, the encapsulation dielectric material that provides the encapsulation spacer 36 can include atoms of boron. In one example, the encapsulation dielectric material that provides the encapsulation spacer 36 can be composed of an SiNC dielectric material that can contain atoms of silicon, carbon, hydrogen, nitrogen and oxygen. In alternative example, the encapsulation dielectric material that provides the encapsulation spacer 36 can be composed of a SiBCN dielectric material that contains atoms of silicon, boron, carbon, hydrogen, and nitrogen. It is noted that encapsulation dielectric material that provides the encapsulation spacer 36 is compositionally different from the dielectric material that provides the sacrificial dielectric layer 24.

The encapsulation spacer 36 can be formed by depositing a conformal layer of an encapsulation dielectric material on physically exposed surfaces (i.e., sidewalls and topmost surface) of the MTJ-containing pillar 26 and on a physically exposed surface of the patterned second ILD layer 20 and on a portion of the sacrificial dielectric layer 24. As used herein, the term “conformal layer” denotes that a material layer has a vertical thickness along horizontal surfaces that is substantially the same (i.e., within ±5%) as the lateral thickness along vertical surfaces. The conformal layer of encapsulation dielectric material can be formed by a conformal deposition process, including but not limited to, ALD, CVD, PECVD or PVD. The formation of the encapsulation spacer 36 continues by removing the conformal layer of encapsulation dielectric material from all horizonal surfaces of the exemplary structure, while maintaining the conformal layer of encapsulation dielectric material along the sidewall of the MTJ-containing pillar 26. The remaining conformal layer of encapsulation dielectric material that is present along the sidewall of the MTJ-containing pillar 26 can be referred to herein as encapsulation spacer 36. The encapsulation spacer 36 is pillar shaped and laterally surrounds the MTJ-containing pillar 26. The removal of the conformal layer of encapsulation dielectric material from all horizonal surfaces can include a dielectric etch back process. As is illustrated in FIG. 3H, the encapsulation spacer 36 is located on a sidewall of each of the bottom magnetic material containing layer 28, the tunnel barrier layer 30 and the upper magnetic material containing layer 32. On one side (this side will later be referred to a second side, S2) of the MTJ-containing pillar 26, the encapsulation spacer 36 has a bottommost surface that is in direct physical contact with a topmost surface of the patterned second ILD layer 20, and a topmost surface that is substantially coplanar with a topmost surface of the MTJ-containing pillar 26. One another side (this side will later be referred to a first side, S1) of the MTJ-containing pillar 26, the encapsulation spacer 36 has a bottommost surface that is in direct physical contact with a topmost surface of the sacrificial dielectric layer 24, and a topmost surface that is substantially coplanar with a topmost surface of the MTJ-containing pillar 26

Referring now to FIG. 3I, there is illustrated the exemplary structure of FIG. 3H after forming a third ILD layer 38 laterally adjacent to, and above, the MTJ-containing pillar 26. The third ILD layer 38 is disposed on the patterned second ILD layer 20. The third ILD layer 38 is also formed beneath the MTJ-containing pillar 26 and in contact with a sidewall and a topmost surface of the sacrificial dielectric layer 24. The third ILD layer 38 can include a dielectric material as mentioned above for the first ILD layer 10. The dielectric material that provides the third ILD layer 38 can be compositionally the same as, or compositionally different from, the dielectric material that provides the first ILD layer 10 and/or the patterned second ILD layer 20. The dielectric material that provides the third ILD layer 38 is however compositionally different from the dielectric material that provides the encapsulation spacer 36 and the sacrificial dielectric layer 24. The third ILD layer 38 can be formed by a deposition process such as, for example, CVD, PECVD, evaporation or spin-on coating. A planarization process such as, for example, CMP, can follow the deposition of the dielectric material that provides the third ILD layer 38.

Referring now to FIG. 3J, there is illustrated the exemplary structure of FIG. 3I after forming a bottom electrode forming patterned mask 40 on the third ILD layer 38, the bottom electrode forming patterned mask 40 having an opening 42 formed therein that physically exposes a surface of the third ILD layer 38. In the present application, the opening 42 is formed above a portion of the MTJ-containing pillar 26 and on a side, i.e., first side, S1, of the MTJ-containing pillar 26 such that the opening 42 is located above a portion of the sacrificial dielectric layer 24. The bottom electrode forming patterned mask 40 is composed of a dielectric hard mask material such as, for example, silicon dioxide, silicon nitride and/or silicon oxynitride. The bottom electrode forming patterned mask 40 can be formed by deposition of a blanket layer of dielectric hard mask material on the third ILD layer 38, followed by lithographic patterning as defined above. The deposition of the blanket layer of dielectric hard mask material can include, but is not limited to, CVD, PECVD or PVD.

Referring now to FIG. 3K, there is illustrated the exemplary structure of FIG. 3J after extending the depth of the opening 42 through the third ILD layer 38 to provide an extended depth opening 42E that physically exposes a surface of the sacrificial dielectric layer 24. The extended depth opening 42 also physically exposes a portion of the topmost surface of the MTJ-containing pillar 26. The extending of the depth of the opening 42 that provides the extended depth opening 42E can include an etch such as, for example, RIE.

Referring now to FIG. 3L, there is illustrated the exemplary structure of FIG. 3K after removing the sacrificial dielectric layer 24 to provide a bottom electrode opening 44 in the both the third ILD layer 38 and the second ILD layer 20 and thereafter removing the bottom electrode forming patterned mask 40, the bottom electrode opening 44 extending beneath a portion of the MTJ-containing pillar 26. The removal of the sacrificial dielectric layer 24 can be performed utilizing an etching process that is selective in removing the sacrificial dielectric layer. After removing the sacrificial dielectric layer 24, the bottom electrode forming patterned mask 40 is removed utilizing a material removal process (i.e., etching or planarization) that is selective in removing the bottom electrode forming patterned mask 40.

Referring now to FIG. 3M, there is illustrated the exemplary structure of FIG. 3L after forming a bottom electrode 46 in a lower portion of the bottom electrode opening 44. The bottom electrode 46 extends beneath MTJ-containing pillar 26 and is located laterally adjacent to the first side, S1, of the MTJ-containing pillar 26. The bottom electrode 46 is located entirely on one side of the vertical Y-Y axis. The forming of the bottom electrode 46 includes filling the bottom electrode opening 44 with a bottom electrode material containing layer. The bottom electrode material containing layer is composed of a conductive metal-containing material such as, for example, Ta, TaN, Ti, TiN, Ru, RuN, RuTa, RuTaN, W, WN or any combination thereof. The filling of the bottom electrode opening 44 with the bottom electrode material containing layer includes deposition of a conductive metal-containing material, followed by a planarization process. The deposition of the conductive metal-containing material can include, but is not limited to, CVD, PECVD, ALD, sputtering or plating. At this point of the present application, the bottom electrode opening 44 is substantially filled with the bottom electrode material containing layer; the bottom electrode material containing layer is also formed on top of the third ILD layer 38. A planarization process such as, for example, CMP, is then used to remove the bottom electrode material containing layer that is formed outside of the bottom electrode opening 44 and on top of the third ILD layer 38. After planarization, the bottom electrode material containing layer that is present in bottom electrode opening 44 is recessed to a height that is typically between a topmost surface and a bottommost surface of the bottom magnetic material containing layer 28 of the MTJ-containing pillar 26. The recessing of the bottom electrode material containing layer includes an etching process such as, for example, RIE, that is selective in removing the bottom electrode material containing layer. The recessing of the bottom electrode material containing layer forms bottom electrode 46 in a bottom portion of the bottom electrode opening 44. In this embodiment, the bottom electrode 46 has a bottommost surface that is in direct physical contact with the metal cap 18 and a topmost surface that is typically located between the topmost surface and the bottommost surface of the bottom magnetic material containing layer 28 of the MTJ-containing pillar 26. In this embodiment, the bottom electrode 46 is in direct physical contact with a bottommost surface of the MTJ-containing pillar 26 as is illustrated in FIG. 3M. As is illustrated, the bottom electrode 46 is direct physical contact with a sidewall and a bottommost surface of the encapsulation spacer 36.

Referring now to FIG. 3N, there is illustrated the exemplary structure of FIG. 3M after forming additional ILD material in an upper portion of the bottom electrode opening 44. The additional ILD material is typically a compositionally same dielectric material as that of the dielectric material that is used in providing the third ILD layer 38. The additional ILD material fills in the upper portion of the bottom electrode opening 44 and re-establishes the third ILD layer 38 as is illustrated in FIG. 3N. The additional ILD material can be formed by deposition, followed by a planarization process.

Referring now to FIG. 3O, there is illustrated the exemplary structure of FIG. 3N after forming a top electrode forming patterned mask 48 on the third ILD layer 38, the top electrode forming patterned mask 48 having an opening 50 formed therein that physically exposes a surface of the third ILD layer 38. In the present application, the opening 50 is formed on the second side, S2, of the MTJ-containing pillar 26 such that the opening 50 is located on a side of the MTJ-containing pillar 26 that is opposite the side, i.e., first side, S1, containing the bottom electrode 46. The top electrode forming patterned mask 48 is composed of a dielectric hard mask material such as, for example, silicon dioxide, silicon nitride and/or silicon oxynitride. The top electrode forming patterned mask 48 can be formed by deposition of a blanket layer of dielectric hard mask material on the third ILD layer 38, followed by lithographic patterning as defined above. The deposition of the blanket layer of dielectric hard mask material can include, but is not limited to, CVD, PECVD or PVD.

Referring now to FIG. 3P, there is illustrated the exemplary structure of FIG. 3O after forming a top electrode opening 51 in the third ILD layer 38 and thereafter removing the top electrode forming patterned mask 48, the top electrode opening 51 extending on top of a portion of the MTJ-containing pillar 26 and located laterally adjacent to the second side, S2, of the MTJ-containing pillar 26 in which the second side, S2, of the MTJ-containing pillar 26 is opposite the first side, S1, of the MTJ-containing pillar 26. The top electrode opening 51 is formed by an etching process that removes physically exposed portions of the third ILD layer 38 that are not protected by the top electrode forming patterned mask 48. After forming the top electrode opening 51, the top electrode forming patterned mask 48 can be removed utilizing a material removal process (i.e., etching or planarization) that is selective in removing the top electrode forming patterned mask 48.

Referring now to FIG. 3Q, there is illustrated the exemplary structure of FIG. 3P after forming a top electrode 52 in the top electrode opening 51 and laterally adjacent to the second side, S2, of the MTJ-containing pillar 26. The top electrode 52 is located entirely on an opposing side of the vertical Y-Y axis as compared to the bottom electrode 46 such that the top electrode 52 and the bottom electrode 46 are non-overlapping and vertically offset from each other. The forming of top electrode 52 includes filling the top electrode opening 51 with a top electrode material containing layer. The top electrode material containing layer is composed of a conductive metal-containing material such as, for example, Ta, TaN, Ti, TiN, Ru, RuN, RuTa, RuTaN, W, WN or any combination thereof. The conductive metal-containing material that provides the top electrode material containing layer can be compositionally the same as, or compositionally different from the conductive metal-containing material that provides the bottom electrode 46. The filling of the top electrode opening 51 with the top electrode material containing layer includes deposition of a conductive metal-containing material, followed by a planarization process. The deposition of the conductive metal-containing material can include, but is not limited to, CVD, PECVD, ALD, sputtering or plating. At this point of the present application, the top opening 51 is substantially filled with the top electrode material containing layer; the top electrode material containing layer is also formed on top of the third ILD layer 38. A planarization process such as, for example, CMP, is then used to remove the top electrode material containing layer that is formed outside of the top electrode opening 51 and on top of the third ILD layer 38.

In this embodiment, the top electrode 52 is in direct physical contact with a topmost of the MTJ-containing pillar 26 and a topmost and a sidewall of the encapsulation spacer 36 as is illustrated in FIG. 3Q. As is also illustrated in FIG. 3Q, the top electrode 52 has a topmost surface that is substantially coplanar with a topmost surface of the third ILD layer 38. In the present application, the top electrode 52 and the bottom electrode 46 are not aligned along a same vertical axis with respect to a plane of an underlying substrate (e.g., the first ILD layer 10). In the present application, the top electrode 52 is present on a side, i.e., the second side, S2, of the MTJ-containing pillar 26 that is opposite the side, i.e., first side, S1, of the MTJ-containing pillar 26. The top electrode 52 and the bottom electrode 46 have a horizontal portion, P1, that is connected to a vertical portion, P2. In the present application, the lateral width, W, of the horizontal portion, P1, of the top electrode 52 and the bottom electrode 46 is greater than a vertical height, H, of the vertical portion, P2, of the top electrode 52 and the bottom electrode 46.

It is noted that it is possible to change the sequence of the above processing flow such that the top electrode 52 is formed prior to the bottom electrode 46.

Referring now to FIG. 3R, there is illustrated the exemplary structure of FIG. 3Q after forming a fourth ILD layer 54 on the third ILD layer 38 and the top electrode 52. The fourth ILD layer 54 can include a dielectric material as mentioned above for the first ILD layer 10. The dielectric material that provides the fourth ILD layer 54 can be compositionally the same as, or compositionally different from, the dielectric material that provides the first ILD layer 10 and/or the patterned second ILD layer 20 and/or third ILD layer 38.

Referring now to FIG. 3S, there is illustrated the exemplary structure of FIG. 3R after patterning the fourth ILD layer 54 to have an opening 56 formed in the fourth ILD layer 54 that physically exposes at least the top electrode 52. The patterning of the fourth ILD layer 54 includes lithographic patterning as defined above. After forming the opening 56 in the fourth ILD layer 54, an optional second diffusion barrier liner 58 and a second electrically conductive structure 60 are formed in the opening 56 providing the memory device illustrated in FIG. 1. The optional second diffusion barrier liner 58 and the second electrically conductive structure 60 include materials mentioned above for the optional first diffusion barrier liner 12 and the first electrically conductive structure 14, respectively. The optional second diffusion barrier liner 58 and a second electrically conductive structure 60 can be formed utilizing the same technique mentioned above in forming the for the optional first diffusion barrier liner 12 and the first electrically conductive structure 14.

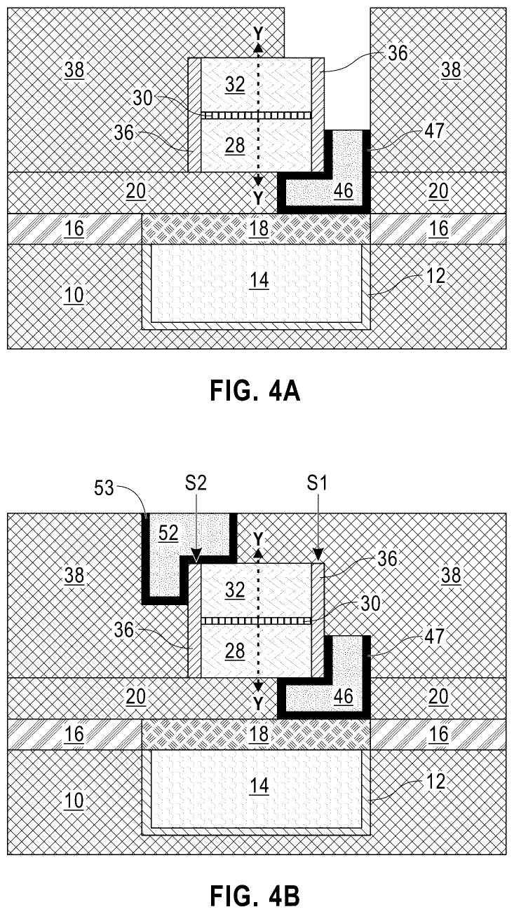

FIGS. 4A-4B illustrates an alternative process flow that can be used in the present application. This alternative process flow provides the memory device illustrated in FIG. 2. The alternative process flows begins by first providing the exemplary structure shown in FIG. 3L utilizing the process flow described for FIGS. 3A-3L above. After providing the exemplary structure shown in FIG. 3L, a bottom electrode diffusion barrier liner 47 and a bottom electrode 46 are formed in a lower portion of the bottom electrode opening 44, the bottom electrode diffusion barrier liner 47 and the bottom electrode 46 extending beneath MTJ-containing pillar 26 and are located laterally adjacent to a first side, S1, of the MTJ-containing pillar 26. The bottom electrode diffusion barrier liner 47 is composed of a diffusion barrier material as mentioned above for the optional first diffusion barrier liner 12. The bottom electrode diffusion barrier liner 47 and the bottom electrode 46 are formed by first depositing a bottom electrode diffusion barrier material layer inside the bottom electrode opening 44 and on top of the third ILD layer 38. After depositing the bottom electrode diffusion barrier material layer, a bottom electrode material containing layer as described above is formed. The bottom electrode material containing layer is deposited directly on the bottom electrode diffusion barrier material layer. A planarization process such as, for example, CMP, is then employed to remove the bottom electrode material containing layer and the bottom electrode diffusion barrier material layer that is formed outside the bottom electrode opening 44 and on top of the third ILD layer 38. A recess etch is then used to reduce the height of the bottom electrode diffusion barrier material layer and the bottom electrode material containing layer that remains in the bottom electrode opening 44. As a result of this recess etch, a bottom electrode diffusion barrier liner 47 and a bottom electrode 46 are formed in a lower portion of the bottom electrode opening 44. In this embodiment, the bottom electrode diffusion barrier liner 47 separates the bottom electrode 46 from each of the encapsulation spacer 36, the bottommost surface of the MTJ-containing pillar, and the metal cap 18. In this embodiment, the bottom electrode diffusion barrier liner 47 has a topmost surface that is substantially coplanar with a topmost surface of the bottom electrode 46.

After providing the structure shown in FIG. 4A, processing as shown in FIGS. 3N-3P is performed and thereafter, a top electrode diffusion barrier liner 53 and a top electrode 52 are formed in the top electrode opening 51 that is present in the third ILD layer 38. The top electrode diffusion barrier liner 53 and the top electrode 52 are formed by first depositing a top electrode diffusion barrier material layer inside the top electrode opening 51 and on top of the third ILD layer 38. After depositing the top electrode diffusion barrier material layer, a top electrode material containing layer as described above is formed. The top electrode material containing layer is deposited directly on the top electrode diffusion barrier material layer. A planarization process such as, for example, CMP, is then employed to remove the top electrode material containing layer and the top electrode diffusion barrier material layer that is formed outside the top electrode opening 51 and on top of the third ILD layer 38. The top electrode diffusion barrier liner 53 and the top electrode 52 are formed on top of the MTJ-containing pillar 26 and laterally adjacent to the second side of the MTJ-containing pillar 26. In this embodiment, the top electrode diffusion barrier liner 53 separates the top electrode 52 from each of the encapsulation spacer 36 and the topmost surface of the MTJ-containing pillar 26. In this embodiment, the top electrode diffusion barrier liner 53 has a topmost surface that is substantially coplanar with a topmost surface of the top electrode 52 and the topmost surface of each of the top electrode diffusion barrier liner 53 and the top electrode 52 are substantially coplanar with the topmost surface of the third ILD layer 38. In the present application, the top electrode 52 and the bottom electrode 46 are not aligned along a same vertical axis with respect to a plane of an underlying substrate (i.e., the first ILD layer 10). In the present application, the top electrode 52 is present on a side, i.e., the second side, S2, of the MTJ-containing pillar 26 that is opposite the side, i.e., first side, S1, of the MTJ-containing pillar 26. Like in the previous embodiment of the present application, the top electrode 52 and top electrode diffusion barrier liner 53 can be formed prior to forming the bottom electrode 46 and bottom electrode diffusion liner 47.

After providing the exemplary structure shown in FIG. 4B, the process steps illustrated by FIGS. 3R and 3S are then performed and thereafter an optional second diffusion barrier liner 58 and a second electrically conductive structure 60 are formed in the opening 56 providing the memory device illustrated in FIG. 2. The optional second diffusion barrier liner 58 and the second electrically conductive structure 60 include materials mentioned above for the optional first diffusion barrier liner 12 and the first electrically conductive structure 14, respectively. The optional second diffusion barrier liner 58 and a second electrically conductive structure 60 can be formed utilizing the same technique mentioned above in forming the for the optional first diffusion barrier liner 12 and the first electrically conductive structure 14. Although not specifically shown in FIG. 4B (but readily discernable from FIG. 3Q), the top electrode 52 and the bottom electrode 46 have a horizontal portion, P1, that is connected to a vertical portion, P2. In the present application, the lateral width, W, of the horizontal portion, P1, of the top electrode 52 and the bottom electrode 46 is greater than a vertical height, H, of the vertical portion, P2, of the top electrode 52 and the bottom electrode 46. Although FIG. 4B shows the presence of bottom electrode diffusion barrier liner 47 and top electrode diffusion barrier liner 53, embodiments are contemplated in which only one of the electrode diffusion barrier liners (i.e., bottom electrode diffusion barrier liner 47 or top electrode diffusion barrier liner 53) is present.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory device comprising:
a magnetic tunnel junction (MTJ)-containing pillar;
a bottom electrode located beneath the MTJ-containing pillar; and
a top electrode located above the MTJ-containing pillar, wherein the bottom electrode and the top electrode are non-overlapping and vertically offset from each other.

2. The memory device of claim 1, wherein the bottom electrode is present along a first side of the MTJ-containing pillar, and the top electrode is present along a second side of the MTJ-containing pillar, wherein the second side is opposing the first side.

3. The memory device of claim 1, wherein each of the top electrode and the bottom electrode includes a horizontal portion that is connected to a vertical portion.

4. The memory device of claim 3, wherein the horizontal portion has a lateral width that is greater than a vertical height of the vertical portion.

5. The memory device of claim 1, wherein the MTJ-containing pillar comprises a bottom magnetic material containing layer, a tunnel barrier layer and an upper magnetic material containing layer, wherein the bottom magnetic material containing layer comprises a magnetic free material, and the upper magnetic material containing layer comprises a magnetic reference material.

6. The memory device of claim 1, wherein the MTJ-containing pillar comprises a bottom magnetic material containing layer, a tunnel barrier layer and an upper magnetic material containing layer, wherein the bottom magnetic material containing layer comprises a magnetic reference material, and the upper magnetic material containing layer comprises a magnetic free material.

7. The memory device of claim 1, wherein the MTJ-containing pillar is laterally surrounded by an encapsulation spacer.

8. The memory device of claim 1, further comprising a first electrically conductive structure located beneath, and electrically connected to, the bottom electrode by a metal cap.

9. The memory device of claim 1, further comprising a second electrically conductive structure located above, and electrically connected to, the top electrode.

10. The memory device of claim 1, wherein both the bottom electrode and the top electrode are in direct electrical contact with the MTJ-containing pillar.

11. The memory device of claim 1, further comprising a bottom electrode diffusion barrier liner located on a sidewall and a bottommost surface of the bottom electrode, and a top electrode diffusion barrier liner located on a sidewall and a bottommost surface of the top electrode.

12. The memory device of claim 1, wherein the top electrode includes a top electrode diffusion barrier liner, and the bottom electrode is devoid of a bottom electrode diffusion barrier liner.

13. The memory device of claim 1, wherein the bottom electrode includes a bottom electrode diffusion barrier liner, and the top electrode is devoid of a top electrode diffusion barrier liner.

14. A memory device comprising:
a magnetic tunnel junction (MTJ)-containing pillar;
a bottom electrode located beneath the MTJ-containing pillar; and
a top electrode located above the MTJ-containing pillar, wherein the bottom electrode and the top electrode are located on opposite sides of a vertical axis that passes through a middle portion of the MTJ-containing pillar.

15. The memory device of claim 14, wherein each of the top electrode and the bottom electrode includes a horizontal portion that is connected to a vertical portion.

16. The memory device of claim 15, wherein the horizontal portion has a lateral width that is greater than a vertical height of the vertical portion.

17. The memory device of claim 14, wherein both the bottom electrode and the top electrode are in direct electrical contact with the MTJ-containing pillar.

18. The memory device of claim 14, further comprising a bottom electrode diffusion barrier liner located on a sidewall and a bottommost surface of the bottom electrode, and a top electrode diffusion barrier liner located on a sidewall and a bottommost surface of the top electrode.

19. The memory device of claim 14, wherein the top electrode includes a top electrode diffusion barrier liner, and the bottom electrode is devoid of a bottom electrode diffusion barrier liner.

20. The memory device of claim 14, wherein the bottom electrode includes a bottom electrode diffusion barrier liner, and the top electrode is devoid of a top electrode diffusion barrier liner.
